(19) United States
(12) Patent Application Publication
(10) Pub. No.: US 2003/0115520 A1
(43) Pub. Date: Jun. 19, 2003

(54) Method for outputting error signals via monitor connect port and the computer system thereof

(76) Inventor: Min-Tien Shih, Taipei (TW)

Correspondence Address: MERCHANT & GOULD P.C., P.O. BOX 2903, MINNEAPOLIS, MN, 55402-0903, US

(21) Appl. No.: 10/025,221

(22) Filed: Dec. 19, 2001

(51) Int. Cl. G01R 31/28

(52) U.S. Cl. 714/724

(57) ABSTRACT

A method for outputting error signals from a computer system via a monitor connect port. In the invention, the computer system outputs the error signals to a testing means via the monitor connect port during testing, wherein the error signals are processed by the testing means.

### BACKGROUND OF THE INVENTION

1. Field of the Invention

The invention relates to a method for outputting error signals via a monitor connect port and the computer system thereof.

2. Description of the Related Art

In a conventional framework, the computer system, such as a notebook or a desktop PC, produces an error signal during the testing process, and then outputs it into an external testing circuit through a docking station, a port replicator or a parallel/serial port, so as to debug.

However, a prospective design of the computer system tends toward lightness and compact profiles. One object of the prospective design is to be legacy-free by combining or forsaking some connecting ports, simplifying the connection between the computer system and peripheral means. For example, the universal serial bus was invented with this object in mind. Future computer systems will likely not be provided with the conventional connecting ports mentioned above, therefore, the testing circuit will not be feasible.

Computer systems always have a monitor, and thus, will continue to keep the monitor connect port. Consequently, if the error signal can be output into an external testing circuit through the monitor connect port, the problems are solved.

### SUMMARY OF THE INVENTION

To solve the above problems, it is an object of the present invention to provide a method for outputting error signals, wherein a computer system outputs the error signals via the monitor connect port.

Another object of the invention is to provide a computer system which outputs the error signals via the monitor connect port during the testing process.

To achieve the above objects, the invention provides a method for outputting error signals by a computer system, comprising the steps of selecting an idle signal line from the signal lines of a monitor connect port, delivering the error signals to the idle signal-line during the testing process, and providing a testing means connecting with the computer system via the idle signal line. When the computer system performs the testing process, the testing means receives the error signals from the idle signal line of the monitor connect port.

To achieve the above objects, the invention provides a computer system comprising a mainframe, a control chip set, an image control device, and a monitor connect port connecting with a monitor. One feature of the computer system is that the image control device controls the monitor via the first set of signal lines of the monitor connect port, and the idle signal lines of the monitor connect port connects with the control chip set to outputs the error signals. The computer system outputs the error signals via the idle signal lines of the monitor connect port during the testing process.

According to the method and computer system of the invention, the error signals are transmitted in the idle signal line by a switch control device. When the computer system connects with a monitor, the switch control device is turned off and so the error signals cannot be transmitted in the idle signal line. When the monitor is disconnected from the computer system, the switch control device is turned on and so the error signals are transmitted in the idle signal line. As well, the switch control device has a control portion. When the monitor is disconnected from the computer system, the control portion has a bias of first voltage so as to turn on the switch control device. When the monitor connects with the computer system, the bias of the control portion is changed from first voltage to second voltage so as to turn off the switch control device.

### BRIEF DESCRIPTION OF THE DRAWINGS

This and other objects and features of the invention will become clear from the following description, taken in conjunction with the preferred embodiments with reference to the drawings, in which:

FIG. 1 is a schematic diagram showing the structure of the computer system of the invention;

FIG. 2 is a schematic diagram showing the configuration of the monitor connect port of the computer system during the testing process.

### DETAILED DESCRIPTION OF THE PREFERRED EMBODIMENTS

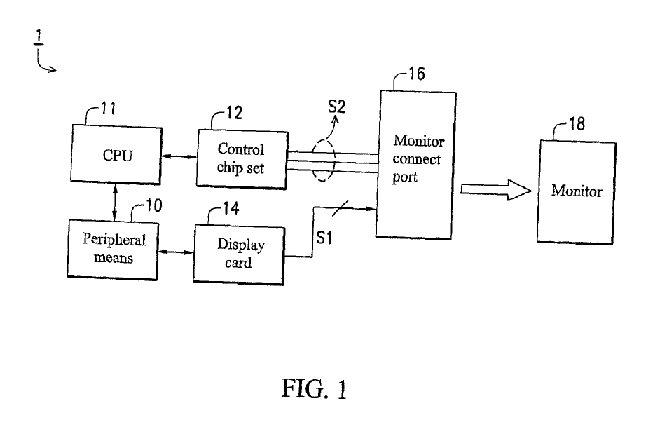

FIG. 1 is a schematic diagram showing the structure of the computer system 1 of the invention. The computer system 1, such as a notebook or a desktop PC, includes a mainframe, a control chip set 12 and a monitor connect port 16 connecting with a monitor 18, wherein the mainframe has a CPU 11, a peripheral means 10, a display card 14 . . . etc. The display card 14 outputs image through the signal lines S1 of the monitor connect port 16, and then the computer system 1 displays an image on the monitor 18. The idle signal lines S2 of the monitor connect port 16, not used by the display card 14, deliver the error signal output by the control chip set 12. The error signals are directly delivered to the idle signal lines S2 or delivered to the idle signal lines S2 by a switch control device (not shown in FIG. 1).

The computer system 1 may produce error signals during testing, and then the control chip set 12 outputs the results into a testing means via the idle signal lines S2 of the monitor connect port 16. Further, the results are processed by the testing means.

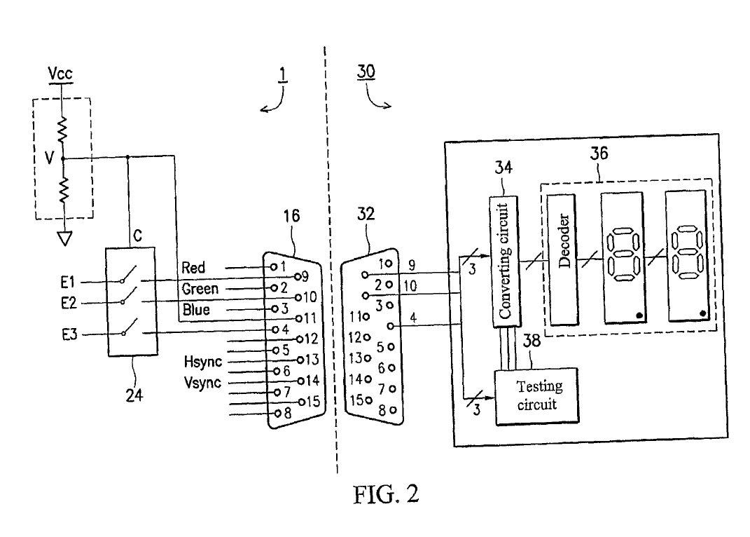

FIG. 2 is a schematic diagram showing the configuration of the monitor connect port 16 of the computer system 10 during the testing process. As well, FIG. 2 only shows part of the computer system 10, such as the monitor connect port 16 and the switch control device 24. In the embodiment, the monitor connect port 16 has fifteen signal lines (or pins), and the numbers of each hollow point represent the pin position, wherein part of the pins marks the meaning of each signal. The fourth 4, ninth 9 and tenth pins 10 of the monitor connect port 16 are idle and not used by the display card, and the other signal lines of the monitor connect port 16 connect with the display card (not shown).

The method for outputting error signals via the monitor connect port includes the steps listed below. First, the desired idle signal lines are selected from the signal lines of the monitor connect port 16. In the embodiment, The fourth 4, ninth 9 and tenth pins 10 of the monitor connect port 16 are selected as the idle signal lines.

The computer system 1 produces the error signals E1, E2, E3 during the testing process. The error signals E1, E2, E3 are respectively delivered to the fourth 4, ninth 9 and tenth pins of the monitor connect port 16 by a switch control device 24. The switch control device has an input port for receiving the error signals, an output port for connecting with the idle signal lines, and a control portion C. The control portion C of the switch control device 24 connects to the power node V providing a first voltage V and the eleventh pin 11 of the monitor connect port 16.

When the computer system 1 is undergoing testing, the eleventh pin 11 of the monitor connect port 16 is disconnected (or does not connect with the monitor). The control portion C of the switch control device 24 is provided with the first voltage, so as to turn on the switch control device 24. Furthermore, the error signals E1, E2, E3 are respectively output via the fourth 4, ninth 9, and tenth pins 10 of the monitor connect port 16. When the computer system 1 connects with the monitor, the eleventh pin 11 of the monitor connect port 16 connects to the internal circuit of the monitor. Thus, the control portion C of the switch control device 24 is changed to the second voltage, so as to turn off the switch control device 24. The error signals E1, E2, E3 are separated from the monitor to prevent interference.

The testing means 30 for dealing with the error signals includes a connect port 32, a converting circuit 34, message display 36, and a testing circuit 38, wherein the pins of the connect port 32 respectively correspond to the monitor connect port 16.

The testing means 30 connects with the computer system 1 through the connect port 32 and monitor connect port 16. When the computer system 1 is undergoing testing, the switch control device 24 is turned on. Furthermore, the error signals E1, E2, E3 are output via the fourth 4, ninth 9 and tenth pins 10 of the monitor connect port 16, and received by the converting circuit 34 and the testing circuit 38. The converting circuit 34, such as a shift register, a serial to parallel conversion . . . etc, converts the error signal, so as to enable the message display 36, such as a seven segment LED . . . etc. As well, the error signals E1, E2, E3 can be particularly processed by the testing circuit 38, and then fed back a control signal to the computer system 1 (not shown).

The computer system can output the error signals via the monitor connect port by the method mentioned above. Further, the invention solve the problems mentioned in the prior art.

While the preferred embodiment of the present invention has been described, it is to be understood that modifications will be apparent to those skilled in the art without departing from the spirit of the invention. The scope of the invention, therefore, is to be determined solely by the following claims.

What is claimed is:

1. A method for outputting error signals via a monitor connect port, comprising the steps of:
selecting a predetermined set of idle signal lines from the signal lines of the monitor connect port;
delivering the error signals generating from a computer system to the predetermined set of idle signal lines respectively during the testing process; and
providing a testing means for processing the error signals during testing, wherein the testing means connects with the monitor connect port and receives the error signals via the predetermined set of idle signal lines.

2. A method for outputting error signals via a monitor connect port as claimed in claim 1, further comprising the step of controlling the error signals by a switch control device whether the error signals are transmitted in the predetermined set of idle signal lines or not; when the computer system connects with a monitor, the switch control device is turned off and cannot deliver the error signals to the predetermined set of idle signal lines, and when the computer system does not connect with a monitor, the switch control device is turned on and delivers the error signals to the predetermined set of idle signal lines.

3. A method for outputting error signals via a monitor connect port as claimed in claim 2, wherein the switch control device includes a control portion; when the computer system is disconnected from the monitor, the control portion has a bias of first voltage, so as to turn on the switch control device, and when the computer system connects with the monitor, the control portion of the switch control device is changed to the second voltage, so as to turn off the switch control device.

4. A computer system for outputting error signals via a monitor connect port during the testing process, comprising a mainframe, a control chip set, an image control device, and a monitor connect port connecting with a monitor; which is characterized in that:
the image control device connects with a monitor via a first set of signal lines; and
the idle signal lines of the monitor connect port, which is not used by the image control device outputs the error signals from the control chip set.

5. A computer system for outputting error signals via a monitor connect port during the testing process as claimed in claim 4, further comprising a switch control device having an input port for receiving the error signals and an output port for connecting with the idle signal lines, when the computer system connects with the monitor, the switch control device is turned off and cannot deliver the error signals to the idle signal lines, and when the computer system does not connect with a monitor, the switch control device is turned on and the error signals are output via the idle signal lines of the monitor connect port.

6. A computer system for outputting error signals via a monitor connect port during the testing process as claimed in claim 5, wherein the switch control device includes a control portion; when the computer system is disconnected from the monitor, the control portion has a bias of first voltage, so as to turn on the switch control device, and when the computer system connects with the monitor, the bias of the control portion of the switch control device is changed from the first voltage to the second voltage, so as to turn off the switch control device.
